(19) United States
(12) Patent Application Publication
(10) Pub. No.: US 2003/0089935 A1
(43) Pub. Date: May 15, 2003

(54) Non-volatile semiconductor memory device with multi-layer gate insulating structure

(75) Inventors: Tso-Hung Fan, Taipei (TW); Tao-Cheng Lu, Kaohsiung (TW); Samuel Pan, Hsin-Chu (TW); Ta-Hui Wang, Hsin-Chu (TW)

Correspondence Address: LOWE HAUPTMAN GILMAN & BERNER, LLP, Suite 310, 1700 Diagonal Road, Alexandria, VA, 22314, US

(73) Assignee: MACRONIX INTERNATIONAL CO., LTD.

(21) Appl. No.: 09/986,931

(22) Filed: Nov. 13, 2001

(51) Int. Cl. H01L 27/108; H01L 29/76

(52) U.S. Cl. 257/296

(57) ABSTRACT

A non-volatile semiconductor memory device with a multi-layer gate insulating structure is provided. The non-volatile semiconductor memory device comprises a gate insulating structure formed between a gate and a channel region, which includes a top silicon nitride layer, an intermediate silicon nitride layer and a bottom silicon nitride layer. When an electric field is applied between the gate and a drain region beside the channel region, hot carriers exhibit a direct tunneling across the bottom silicon nitride layer from the drain region for a write-erase operation. The hot carriers having exhibited the direct tunneling from the drain region are trapped into the intermediate silicon nitride layer.

### BACKGROUND OF THE INVENTION

1. Field of the Invention

The present invention relates in general to a non-volatile memory device, and more particularly to a non-volatile memory device with a multi-layer gate insulating structure.

2. Description of the Prior Art

Typical semiconductor memory utilized during microprocessor operation is volatile. That is in the case of power interruption, the data stored in the semiconductor memory is typically completely lost. One way to circumvent this problem is to provide separate backup of the memory, such as battery power or capacitor storage. An alternate technique would be to make the memory fundamentally non-volatile. This operation is highly desirable because non-volatile semiconductor memories would not only withstand power interruption, but also would be stored or shipped without being energized.

Typical prior art non-volatile memory devices are charge-trapping devices. Examples include metal nitride-oxide-semiconductor (MNOS); silicon-nitride-oxide-semiconductor (SNOS); and silicon-oxide-nitride-oxide-semiconductor (SONOS) memory device.

A typical metal-nitride-oxide-semiconductor (MNOS) memory device is as illustrated in FIG. 1. The typical MNOS memory device 1 comprises a semiconductor substrate 10, a source/drain region 11 formed in the semiconductor substrate 10, a channel region 12 defined between the pair of source/drain region 11, a silicon dioxide layer 13 formed on the channel region 12, a silicon nitride layer 14 formed on the silicon dioxide layer 13 and an aluminum gate 15 formed on the silicon nitride layer 14.

In the write operation of the MNOS memory device 1, a positive voltage is applied to the gate so that an electric field is applied across the above four layer laminations (10, 13, 14, 15) to cause hot electrons on a surface region of the semiconductor substrate 10. The hot electrons may show either a Fowler-Nordheim tunneling or a direct tunneling across the silicon dioxide layer 13 and then trapped into an interface between the silicon dioxide layer 13 and the silicon nitride layer 14.

In the erasing operation, a negative voltage is applied to the gate so that the electrons trapped in the interface between the above two layers may show a reverse direction Fowler-Nordheim tunneling or a reverse direction direct tunneling across the silicon dioxide layer 13 into the semiconductor substrate 10. Thereby, the electrons have emitted from the interface between the silicon dioxide layer 13 and the silicon nitride layer 14.

In the write operation, although the majority of hot electrons are trapped into the interface between the silicon dioxide layer 13 and the silicon nitride layer 14, while the minority of the hot electrons inclines to penetrate into the silicon nitride layer 14. The hot electrons penetrating into the silicon nitride layer 14 will cause an unnecessary electric field. Even when no voltage applied on the gate for a long-time storage, such the unnecessary electric field will allow the electrons trapped in the interface between the silicon dioxide layer 13 and silicon nitride layer 14 show gradual emissions through the reverse direction tunneling across the silicon dioxide layer 13. Then, a considerable amount of electrons may be emitted from this interface. This renders it hard to trap the information electrons on the interface between the silicon dioxide layer 13 and the silicon nitride layer 14 or to achieve a long-term storage of information.

In order to improve the charge retention of the MNOS memory device 1, a SNOS (silicon-nitride-oxide-semiconductor) memory device has been developed. The SNOS memory device employs a nitride layer deposited by low-pressure chemical vapor deposition and hydrogen anneal which improves the quality of the interfaces. The retention of the SNOS memory device improves as the thickness of the nitride layer is reduced; unfortunately this leads to enhanced hole injection from the gate. In order to eliminate this problem, a top oxide layer is used between the gate and the nitride, thus obtaining a SONOS (silicon-oxide-nitride-oxide-semiconductor) memory device.

A typical SONOS memory device 2 is as illustrated in FIG. 2. The typical SONOS memory device 2 comprises a semiconductor substrate 20, a source/drain region 21 formed in the semiconductor substrate 20, a channel region 22 defined between the pair of source and drain regions 21, a bottom silicon dioxide layer 23 formed on the channel region 22, an intermediate silicon nitride layer 24 formed on the bottom silicon dioxide layer 23, a top silicon dioxide layer 25 formed on the intermediate silicon nitride layer 24 and a polysilicon gate 26 formed on the top silicon dioxide layer 25. The programming operation is performed by electron Fowler-Nordheim injection from the semiconductor substrate 20 into the intermediate silicon nitride layer 24, while the erasing operation is performed by hole Fowler-Nordheim injection from the polysilicon gate 26 into the intermediate silicon nitride layer 24. The main disadvantage of Fowler-Nordheim programming is the need of a high electric field, which is crucial to determine device reliability and endurance characteristics. The Fowler-Nordheim programming also takes a long programming time.

Accordingly, it is an intention to provide a non-volatile memory device with new gate insulating structure, which can overcome the drawbacks of the above prior non-volatile memory device.

### SUMMARY OF THE INVENTION

It is an objective of the present invention to provide a non-volatile semiconductor memory device with a gate insulating structure including a bottom silicon nitride layer, an intermediate silicon nitride layer and a top silicon nitride layer, the device providing a high efficient hot carrier injection for programming and erasing operations due to the low barrier height of the bottom silicon nitride layer for both electron and hole.

It is anther objective of the present invention to provide a nonvolatile semiconductor memory device with a gate insulating structure including a bottom silicon nitride layer, an intermediate silicon nitride layer and a top silicon nitride layer, which can improve retention characteristic of electron information stored in the intermediate silicon nitride layer.

It is a further objective of the present invention to provide a non-volatile semiconductor memory device with a gate insulating structure including a bottom silicon nitride layer, an intermediate silicon nitride layer and a top silicon nitride layer, which is advantageous for cell scaling due to the high dielectric constant of the three silicon nitride layers.

In order to achieve the above objectives, the present invention provides a non-volatile semiconductor memory device with multi-layer gate insulating structure. The non-volatile semiconductor memory device with a multi-layer gate insulating structure comprises a semiconductor substrate with a first conductivity, a source/drain region with a second conductivity opposite to the first conductivity formed on a surface of the semiconductor substrate, a channel region defined between the source and drain regions on the surface of the semiconductor substrate, a first silicon nitride layer formed on the channel region, a second silicon nitride layer formed on the first silicon nitride layer, a third silicon nitride layer formed on the second silicon nitride layer, and a gate formed of a conductive layer formed on the third silicon nitride layer. When an electric field is applied between the gate and the drain region, hot carriers exhibit a direct tunneling across the first silicon nitride layer from the drain region for a write-erase operation, and the hot carriers having exhibited said direct tunneling from the drain region are trapped into the second silicon nitride layer.

### BRIEF DESCRIPTION OF THE DRAWINGS

The above and other objects, features and advantages of the present invention will be apparent from the following description with reference to accompanying drawings:

FIG. 1 is a cross-sectional view of a prior MNOS type non-volatile memory device;

FIG. 2 is a cross-sectional view of a prior SONOS type nonvolatile memory device;

FIG. 3 is a cross-sectional view of a SNNNS type non-volatile semiconductor memory device in accordance with the present invention; and

FIG. 4 is a schematic energy barrier diagram for both electron and hole associated with the gate structure of FIG. 3.

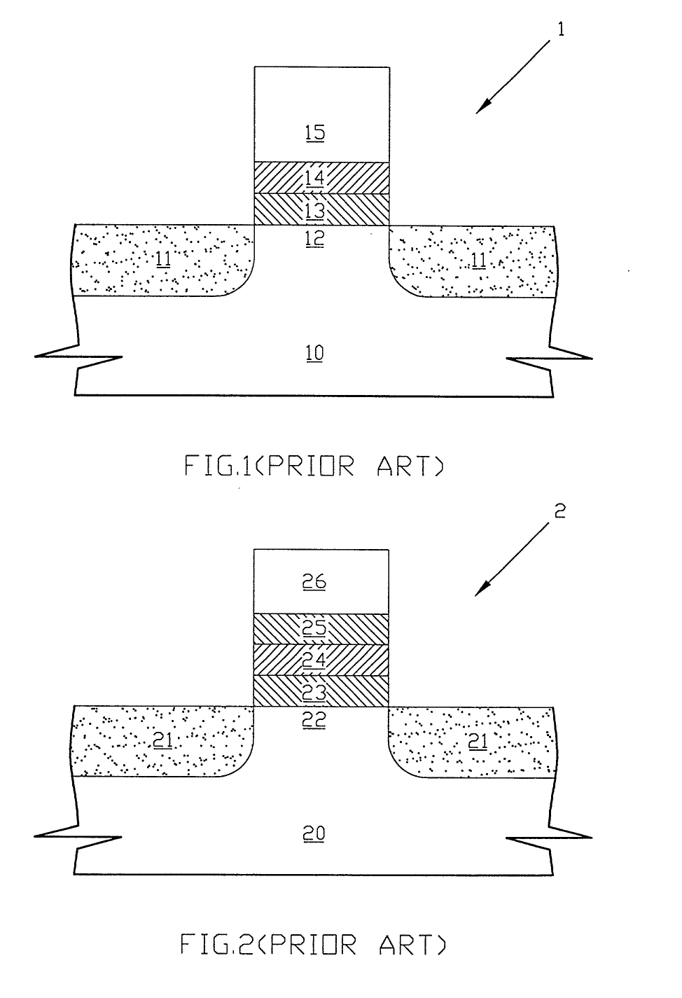

### DESCRIPTION OF THE PREFERRED EMBODIMENTS

The present invention provides a non-volatile semiconductor memory device with a new gate structure including three insulating layers made of the same material. A first insulating layer is formed on a semiconductor substrate and a second insulating layer is formed on the first insulating layer. A third insulating layer is formed on the second insulating layer and a conductive layer serving as a gate is formed on the third insulating layer. The present non-volatile semiconductor memory device can be either an N channel non-volatile memory transistor or a P channel non-volatile memory transistor.

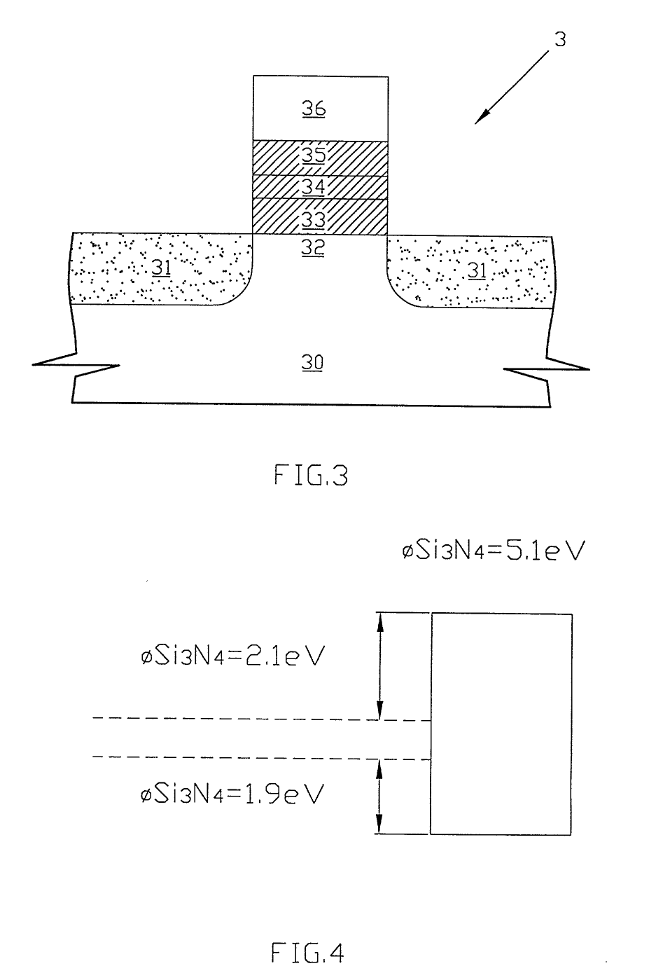

The present invention will be described in detail below in which there is provided a non-volatile memory device 3 with a new silicon-nitride-nitride-nitride-semiconductor (SNNNS) multi-layer structure as illustrated in FIG. 3. A semiconductor substrate comprises a P type silicon substrate 30. A pair of N+buried diffusion regions separated from each other for a distance serving as source/drain regions 31 are formed in the P type silicon substrate 30. An N channel 32 is defined between the source/drain regions 31 and in the P type silicon substrate 30. A first silicon nitride layer 33 having a thickness about 40˜100 angstroms is formed on the N channel 32. A second silicon nitride layer 34 having a thickness in the range of about 40˜100 angstroms is formed on the first silicon nitride layer 33. A third silicon nitride layer 35 having a thickness about 40˜100 angstroms is formed on the second silicon nitride layer 34. A conductive layer, such as a polysilicon layer 36, is formed on the third silicon nitride layer 35. The second silicon nitride layer 34 is used as a charge trapping layer, while the first silicon nitride layer 33 and the third silicon nitride layer 35 are used as tunneling layer.

The programming operation of the present SNNNS type nonvolatile memory device 3 is performed by channel hot electron injection from the drain side through the bottom tunneling layer, i.e. the first silicon nitride layer 33, into the intermediate trapping layer, i.e. the second silicon nitride layer 34. The programming operation is performed by applying a first voltage between the gate of the polysilicon layer 36 and the silicon substrate 30 to turn on the N channel 32 and applying a second voltage between the drain region 31 and source region 31 to induce a current and generate hot electrons that are injected into the second silicon nitride layer 34 through the first silicon nitride layer 33. Preferably, the first voltage is about 6˜10V, the second voltage is about 2.5˜5V, and both of the silicon substrate 30 and the source region 31 are grounded. The erasing operation of the present SNNNS type nonvolatile memory device 3 is performed by the Fowler-Nordheim (FN) cold hole injection from the N channel 32 into the second silicon nitride layer 34 through the first silicon nitride layer 33. The erasing operation is performed by applying a positive bias on the silicon substrate 30 and a negative bias on the gate of the polysilicon layer 36 so as to genetrate Fowler-Nordheim (FN) cold holes that are injected into the second silicon nitride layer 34 through the first silicon nitride layer 33. The cold holes are generated in the N channel 32 in the silicon substrate 30 under the first silicon nitride layer 33 and between the source region 31 and the drain region 31. Preferably, the bias of the gate of the polysilicon layer 36 is about −6˜10V and the bias of the silicon substrate 30 is about 0˜5V.

FIG. 4 is a schematic energy barrier diagram of the first silicon nitride layer 33 for both electron and hole. The first silicon nitride layer 33 serving as the bottom tunneling layer provides a potential barrier about 2.1 electron volts for electron, which is lower than a potential barrier about 3.2 electron volts provided by a silicon dioxide layer. The first silicon nitride layer 33 provides a potential barrier about 1.9 electron volts for hole, which is also lower than a potential barrier about 4.8 electron volts provided by a silicon dioxide layer. Accordingly, the present SNNNS type non-volatile memory device 3 can provide a highly efficient hot carrier injection, for example, in programming and erasing operations, by using the first silicon nitride layer 33 serving as the bottom tunneling layer. Additionally, the first silicon nitride layer 33 has a high dielectric constant, preferably not less than 7, it is advantageous in cell scaling for the present SNNNS type non-volatile memory device 3 to reduce voltage applications in programming and erasing operations. The power consumption of the present SNNNS type non-volatile memory device 3 is accordingly reduced.

The third silicon nitride layer 35, serving as the top tunneling layer, is of good quality, with very little traps. In programming operation, minor hot electrons cannot easily penetrate into the third silicon nitride layer 35. An unnecessary electric field induced by the electrons penetrating into the third silicon nitride layer 35 and trapping therein is avoided. Therefore, the retention characteristic of the electron information stored in the trapping layer, i.e. the second silicon nitride layer 34 is improved.

The preferred embodiment is only used to illustrate the present invention, not intended to limit the scope thereof. Many modifications of the preferred embodiment can be made without departing from the spirit of the present invention.

What is claimed is:

1. A multi-layer structure, comprising:
a semiconductor layer;
a first insulating layer formed on said semiconductor layer, said first insulating layer having a first dielectric constant and having a first thickness;
a second insulating layer formed on said first insulating layer, said second insulating layer having a second dielectric constant and having a second thickness;
a third insulating layer formed on said second insulating layer, said third insulating layer having a third dielectric constant and having a third thickness; and
a conductive layer formed on said third insulating layer so that when an electric field is applied between said semiconductor layer and said conductive layer, hot carriers exhibit a direct tunneling across said first insulating layer from said semiconductor layer, and said hot carriers having exhibited said direct tunneling from said semiconductor layer are trapped into said second insulating layer.

2. The structure of claim 1, wherein said first insulating layer comprises silicon nitride.

3. The structure of claim 1, wherein said second insulating layer comprises silicon nitride.

4. The structure of claim 1, wherein said third insulating layer comprises silicon nitride.

5. The structure of claim 1, wherein said conductive layer comprises polysilicon.

6. The structure of claim 2, wherein said first thickness of said first insulating layer is about 40˜100 angstroms.

7. The structure of claim 3, wherein said second thickness of said second insulating layer is about 40˜100 angstroms.

8. The structure of claim 4, wherein said third thickness of said third insulating layer is about 40˜100 angstroms.

9. A multi-layer structure, comprising:
a semiconductor layer;
a first silicon nitride layer formed on said semiconductor layer, said first silicon nitride layer having a first thickness;
a second silicon nitride layer formed on said first silicon nitride layer, said second silicon nitride layer having a second thickness;
a third silicon nitride layer formed on said second silicon nitride layer, said third silicon nitride layer having a third thickness; and
a conductive layer formed on said third silicon nitride layer so that when an electric field is applied between said semiconductor layer and said conductive layer, hot carriers exhibit a direct tunneling across said first silicon nitride layer from said semiconductor layer, and said hot carriers having exhibited said direct tunneling from said semiconductor layer are trapped into said second silicon nitride layer.

10. The structure of claim 9, wherein said first thickness of said first silicon nitride layer is about 40˜100 angstroms.

11. The structure of claim 9, wherein said second thickness of said second silicon nitride layer is about 40˜100 angstroms.

12. The structure of claim 9, wherein said third thickness of said third silicon nitride layer is about 40˜100 angstroms.

13. The structure of claim 9, wherein said conductive layer comprises polysilicon.

14. A non-volatile semiconductor memory device with a multilayer gate insulating structure, comprising:
a semiconductor substrate with a first conductivity;
a source/drain region with a second conductivity opposite to said first conductivity formed on a surface of said semiconductor substrate;
a channel region defined between said source and drain regions on said surface of said semiconductor substrate;
a first silicon nitride layer formed on said channel region;
a second silicon nitride layer formed on said first silicon nitride layer;
a third silicon nitride layer formed on said second silicon nitride layer; and
a gate formed of a conductive layer formed on said third silicon nitride layer so that when an electric field is applied between said gate and said drain region, hot carriers exhibit a direct tunneling across said first silicon nitride layer from said drain region for a write-erase operation, and said hot carriers having exhibited said direct tunneling from said drain region are trapped into said second silicon nitride layer.

15. The device of claim 14, wherein said first conductivity is either of N type and P type conductivities.

16. The device of claim 14, wherein said first silicon nitride layer is formed with a thickness about 40˜100 angstroms.

17. The device of claim 14, wherein said second silicon nitride layer is formed with a thickness about 40˜100 angstroms.

18. The device of claim 14, wherein said third silicon nitride layer is formed with a thickness about 40˜100 angstroms.

19. The device of claim 14, wherein said conductive layer of said gate comprises polysilicon.
